(19) United States
(12) Patent Application Publication
(10) Pub. No.: US 2025/0167525 A1
(43) Pub. Date: May 22, 2025

(54) OPTICAL MODULE AND PACKAGE MODULE

(71) Applicant: SHENZHEN METALENX TECHNOLOGY CO.,LTD, Shenzhen (CN)

(72) Inventors: Junming DONG, Shenzhen (CN); Chenglong HAO, Shenzhen (CN); Fengze TAN, Shenzhen (CN); Jian ZHU, Shenzhen (CN)

(73) Assignee: SHENZHEN METALENX TECHNOLOGY CO.,LTD, Shenzhen (CN)

(21) Appl. No.: 18/946,850

(22) Filed: Nov. 13, 2024

(30) Foreign Application Priority Data
Nov. 17, 2023 (CN) 202323113177.6
Nov. 17, 2023 (CN) 202323113179.5

(51) Int. Cl. H01S 5/42; H01S 5/02253

(52) U.S. Cl. CPC H01S 5/423; H01S 5/02253

(57) ABSTRACT

An optical module and a package module are provided, and the optical module includes a VCSEL array, a collimating metalens array; and the collimating metalens array is set on an outgoing side of the VCSEL array and are parallel to the VCSEL array. The VCSEL array includes a plurality of VCSELs, and the metalens array includes a plurality of collimating metalenses; the collimating metalens array includes an effective region for light modulation; a projection of an illumination region of the VCSEL array on the collimating metalens array is inside the effective region of the collimating metalens array.

### CROSS-REFERENCE TO RELATED APPLICATIONS

This application claims the benefit of priority from Chinese Patent Application No. 202323113177.6 and No. 202323113179.5, filed on Nov. 17, 2023. The content of the aforementioned application, including any intervening amendments thereto, is incorporated herein by reference in its entirety.

### TECHNICAL FIELD

The present disclosure relates to the field of lenses, in particular to an optical module and a package module.

### BACKGROUND

In many optical products, it is often necessary to set optical modules that can collimate the lights emitted by the light source into parallel light internally. In order to reduce the volume, weight and cost of the optical module, the collimating lens used in the optical module can be set as a metalens. When the light source of the optical module is a light source array, the collimation of the optical module designed by the exist relevant technology will decrease, which will result in the insufficient for the degree of collimation of the optical module.

Moreover, the size of the metalens is usually very small, so it is difficult to align the metalens with the light source, which will lead to the difficulty of packaging the corresponding optical module efficiently.

### SUMMARY

In order to solve the problems in the prior art, an optical module and a package module are provided according to the embodiments of the present application. The optical module reduces the difficulty of packaging the optical module by aligning the center of the metalenses to the center of the VCSELs.

In the first aspect of the present application, an optical module is provided,

On the one hand, the optical module provided by application includes: an optical module, wherein the optical module includes a VCSEL array, a collimating metalens array;
the collimating metalens array is set on an outgoing side of the VCSEL array and are parallel to the VCSEL array;
the VCSEL array includes a plurality of VCSELs, and the metalens array includes a plurality of collimating metalenses; the collimating metalens array includes an effective region for light modulation; a projection of an illumination region of the VCSEL array on the collimating metalens array is inside the effective region of the collimating metalens array;
a plurality of projections of the centers of the VCSELs of the VCSEL array on the effective region overlaps the centers of the collimating metalenses of the collimating metalens array.

In one embodiment, each VCSEL in the VCSEL array emits light has a central wavelength of 810 nm.

In one embodiment, each VCSEL in the VCSEL array emits light has a full angle of divergence of 25°.

In one embodiment, a distance between the VCSEL array and the collimating metalens array is greater than or equal to 250 μm, and is less than or equal to 350 μm.

In one embodiment, a distance between the VCSEL array and the collimating metalens array is greater than or equal to 280 μm, and is less than or equal to 320 μm.

In one embodiment, a number of the metalenses of the collimating metalens array is greater than or equal to a number of the VCSELs of the VCSEL array.

In one embodiment, the effective region of the collimating metalens array faces toward the VCSEL array.

A package module is provided, wherein the package module is applied to the package of the optical module, and the package module includes a first structural element;
the shape of the first structural element is a ring; the first structural element includes a substrate and a vertical eave, and the shape of the substrate is a ring and the shape of the vertical eave is a ring; the vertical eave is set on a first surface of the substrate, and the vertical eave surrounds a hole region of the center of the first surface; an inner wall of the vertical eave and the first surface form a first step structure, and the collimating metalens array is fixed to the first step structure;

In one embodiment, the projection of the effective region of the collimating metalens array on the first surface is inside the hole region of the first surface. In one embodiment, the first surface faces toward the VCSEL array.

In one embodiment, wherein a height of the first step structure is less than a height of the collimating metalens array.

In one embodiment, wherein the package module includes a second structural element;
a third surface of the second structural element and the first structural element are fixed together, and a fourth surface of the second structural element and an outgoing surface of the VCSEL array are fixed together; the third surface and the fourth surface are planes.

In one embodiment, wherein an outer wall of the vertical eave is aligned with an outer wall of the substrate; and the third surface is fixed to a surface facing toward the VCSEL array of the vertical eave.

In one embodiment, an outer wall of the vertical eave and the first surface form a second step structure.

In one embodiment, the third surface is fixed to a platform of the second step structure.

In one embodiment, the third surface and the first structural element are fixed together by dispensing.

In one embodiment, the fourth surface and an outgoing surface of the VCSEL array are fixed together by dispensing.

In one embodiment, a protective element is set on an outgoing surface of the VCSEL array, and the protective element surrounds the center of the VCSEL array.

In one embodiment, a third step structure is set on an inner wall of one end of the protective element that is closed to the first structural element; a projection of the protective element of an outer wall of the collimating metalens array on the VCSEL array is located at a platform of the third step structure.

In one embodiment, a sum of a height of the third step structure and the height of the first step structure is less than the height of the collimating metalens array.

On the one hand, the optical module includes a VCSEL array, a collimating metalens array; and the collimating metalens array is set on an outgoing side of the VCSEL array and is parallel to the VCSEL array. The VCSEL array includes a plurality of VCSELs, and the metalens array includes a plurality of collimating metalenses; the collimating metalens array includes an effective region for light modulation; a projection of an illumination region of the VCSEL array on the collimating metalens array is inside the effective region of the collimating metalens array. A plurality of projections of the centers of the VCSELs of the VCSEL array on the effective region overlaps the centers of the collimating metalenses of the collimating metalens array. It should be noted that for the VCSELs of the VCSEL array, if the metalenses of the metalens array can't be aligned with the VCSELs, the lights emitted by the VCSEL array will be collimated as a prospect. Thus, the degree of collimation of the optical module will not be enough. In this way, the optical module provided by the present application avoids the situation that the lights emitted by the VCSEL array will be collimated as a prospect, which ensures enough degree of collimation of the optical module.

On the other hand, the package module is applied to the package of the optical module, and the package module includes a first structural element; the shape of the first structural element is a ring; the first structural element includes a substrate and a vertical eave, and the shape of the substrate is a ring and the shape of the vertical eave is a ring; the vertical eave is set on a first surface of the substrate, and the vertical eave surrounds a hole region of the center of the first surface; an inner wall of the vertical eave and the first surface form a first step structure, and the collimating metalens array is fixed to the first step structure. Because the size of the first structural element is greater than the size of the metalens array, compared with adjusting the position of the metalens array directly, adjusting the position of the first structural element directly is easier. Moreover, the first step structure of the first structural element ensures high accuracy, and the first step structure of the first structural element will ensure the position accuracy. Therefore, in the optical module provided by the application, the position of the metalens array will be adjusted accurately and indirectly by adjusting the position of the first structural element. It can be seen that with the optical module provided by the application, the position of metalens array can be controlled and adjusted efficiently and accurately. Therefore, in the process of packaging the optical module, the VCSELs of the VCSEL array can be centrally aligned with the metalenses in the metalens array more efficiently, which will reduce the package difficulty of the optical module and improve the package efficiency of the optical module.

Other features and advantages of the present application will become apparent in the detailed description below or will be acquired in part by the practice of the present application.

It should be understood that the above general description and detailed details are exemplary only, and do not limit this application.

### BRIEF DESCRIPTION OF THE DRAWINGS

The present disclosure may be better understood by reference to the description given below in combination with the drawings, where the same or similar drawing markings are used in all the drawings to represent the same or similar assemblies. The drawings are included in the specification along with the following detailed description and form part of the specification, and to further illustrate the preferred embodiments of the disclosure and explain the principles and advantages of the disclosure.

FIG. 1 shows a schematic diagram of the partial structure provided by an embodiment of the present application.

FIG. 2 shows a working diagram of the optical module and a detector provided by an embodiment of the present application.

FIG. 3 shows a schematic diagram of the first structural element of the package module provided by one embodiment of the present application.

FIG. 4 shows a sectional view of the package module provided by one embodiment of the present application.

FIG. 5 shows a sectional view of the package module provided by one embodiment of the present application.

FIG. 6 shows a sectional view of the second structural element of the package module provided by one embodiment of the present application.

FIG. 7 shows a sectional view of the second structural element of the package module provided by one embodiment of the present application.

FIG. 8 shows a sectional view of the second structural element of the package module provided by one embodiment of the present application.

FIG. 9 shows a sectional view of the second structural element of the package module provided by one embodiment of the present application.

FIG. 10 shows a schematic layout of the detection system provided by one embodiment of the present application.

FIG. 11 shows a schematic layout of the detection system provided by an embodiment of this application.

### DETAILED DESCRIPTION OF THE EMBODIMENTS

The embodiment will now be described more comprehensively with reference to the accompanying drawings. However, the embodiments can be implemented in various forms and should not be understood to be limited to the examples elaborated herein; instead, providing these embodiments makes the description of this application more comprehensive and complete and fully communicates the idea of the exemplary embodiment to those skilled in the art. The attached drawings are only schematic illustrations of this application and are not necessarily proportional drawings. The same reference marks in the figure indicate the same or similar parts, and their repeated descriptions will be omitted.

Furthermore, the described features, structures or features may be combined in one or more embodiments in any suitable manner. In the following description, many specific details are provided to give a full understanding of the embodiments of this application. However, those skilled in the art will be aware that one or more of the specific details may be omitted from the present technical solution (or other modules, components etc.) may be adopted. In other cases, aspects of the present application are blurred without detailed showing or describing the public structure, method, implementation or operation to avoid over-dominance.

It should be noted that when the optical module to be packaged is composed of a VCSEL array and a collimating metalens array, it is necessary to align the centers of the VCSELs in the VCSEL array to the centers of the metalenses in the metalens array accurately. However, when the optical module to be packaged is composed of a single light source and a single metalens, it is difficult to align the center of the single metalens with the center of the single light source. Therefore, when the optical module is composed of the VCSEL array and the metalens array, it is more difficult to align the centers of the VCSELs in the VCSEL array with the centers of the metalenses in the metalens array. In order to overcome the above defects in the relevant technology, this application provides an optical module and a package module. In the optical module provided in this application, the optical module has enough degree of collimation.

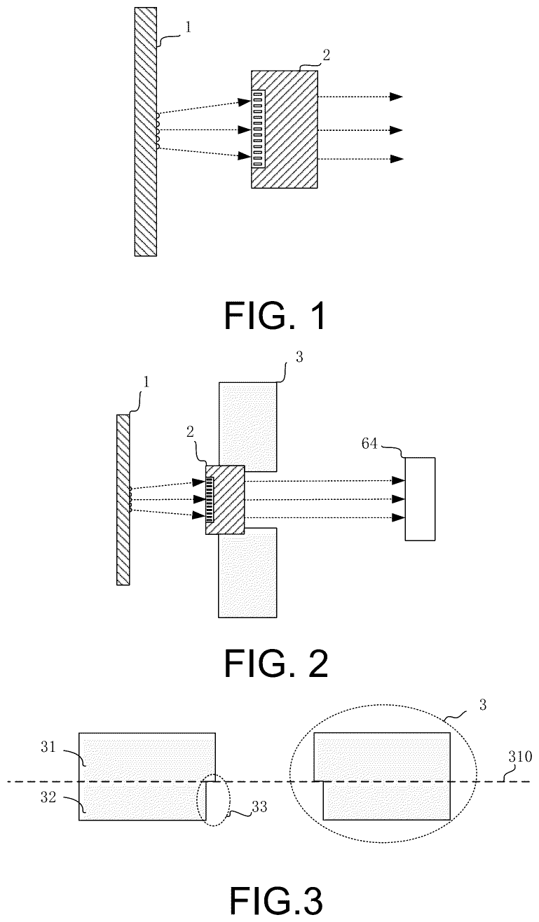

FIG. 1 shows a section view of the optical module provided by the embodiment. As shown in FIG. 1, the optical module includes a VCSEL (Vertical-Cavity Surface-Emitting Laser) array 1 and a collimating metalens array 2. The VCSEL array 1 includes a plurality of VCSELs. The collimating metalens array 2 includes a plurality of collimating metalenses. The collimating metalens array 2 is used to collimate the lights emitted by the VCSEL array 1 to parallel lights.

In detail, the collimating metalens array 2 is set on the outgoing side of the VCSEL array 1, and the collimating metalens array 2 is parallel to the VCSEL array 1. A projection of the illumination region of the VCSEL array 1 on the collimating metalens array 2 is inside the effective region of the collimating metalens array 2 for modulation of lights. The effective region refers to the region of the collimating metalens array 2 provided with nanostructures. The projection of an illumination region of the VCSEL array on the collimating metalens array is inside the effective region of the collimating metalens array, indicating that the alignment of the divergence angle of the light emitted by the VCSELs in the VCSEL array 1 can be ignored. Preferably, the effective region may be appropriately expanded so that all the lights emitted by the VCSEL array 1 are incident to the effective region even when the divergence angles of the lights emitted by VCSELs of the VCSEL array 1 are considered.

And in the present application, a projection of the centers of the VCSELs of the VCSEL array 1 on the effective region overlaps the centers of the collimating metalenses of the collimating metalens array 2. That is, the centers of the VCSELs are aligned with the center of the metalenses. For the VCSELs of the VCSEL array 1, the collimating metalenses of the collimating metalens array 2 are aligned with the VCSELs of the VCSEL array 1. It should be noted that for the VCSELs of the VCSEL array 1, if there is no metalens aligned with the center in the collimating metalens array 2, the light emitted by the VCSEL array will not be collimated as intended, leading to the degree of collimation will be not enough. Therefore, the optical module provided by the present application will avoid the lights emitted by the VCSEL array not to being collimated as intended, thus ensuring the optical module has enough degree of collimation.

In one embodiment, each VCSEL in the VCSEL array emits light and has a central wavelength of 810 nm.

In one embodiment, each VCSEL in the VCSEL array emits light has a full angle of divergence of 25°, that is, the half angle is 12.5°.

In one embodiment, the target working distance between the VCSEL array 1 and the collimating metalens array 2 is 300 μm, and a 50 μm tolerance is allowed. That is, the target working distance is greater than or equal to 250 μm, and is less than or equal to 350 μm. Preferably, the working distance between the VCSEL array and the collimating metalens array 2 is greater than or equal to 280 μm, and is less than or equal to 320 μm.

In one embodiment, the illumination region of the VCSEL array 1 is a rectangle. The target length of the first side length is 1270 μm, the target length of the second side length is 1148 μm, and a tolerance of 10 μm for both the first side length and the second side length are allowed, that is, there may be a fluctuation of 10 μm. Therefore, in this embodiment, the first side length of the illumination region is greater than or equal to 1260 μm and less than or equal to 1280 μm, and the second side length of the illumination region is greater than or equal to 1138 μm and less than or equal to 1158 μm.

In one embodiment, the number of the metalenses of the collimating metalens array 2 is greater than or equal to the number of the VCSELs of the VCSEL array 1. In this way, the centers of metalenses are aligned with the centers of the VCSELs.

Specifically, the VCSELs of the VCSEL array 1 are arranged in a period, and the metalenses of the metalens array are arranged in a period. In this situation, in some embodiments, according to the determined period, some redundant metalens can be provided in the collimating metalens array 2, so that there will be more selections of the relative position between the collimating metalens array 2 and the VCSEL array 1 when the collimating metalens array 2 and the VCSEL array 1 are aligned centrally. Therefore, the centers of the metalenses of the metalens array are aligned with the centers of the VCSELs of the VCSEL array.

It should be noted that when the light propagation or light modulation is performed, the distance between the collimating metalens array 2 and the VCSEL array 1 is mainly determined by the distance between the effective region of the surface of the collimating metalens array 2 and the VCSEL array 1. Therefore, to decrease the lowest limitation of the distance between the effective region of the surface of the collimating metalens array 2 and the VCSEL array 1, in one embodiment, the effective region of the collimating metalens array 2 faces toward the VCSEL array 1. It is beneficial to adjust the working distance between the collimating metalens array 2 and the VCSEL array 1 to the required working distance.

It should be noted that in the optical module provided by the present application, the centers of the VCSELs of the VCSEL array need to be aligned with the centers of metalenses of the metalens array accurately. Because the volume of the metalens array is very small, it is difficult to adjust the position of the metalens array accurately and package the optical module efficiently.

Therefore, a package module is provided, and the package module is used for the optical module. And in the package module, the position of the metalens array can be adjusted and controlled efficiently and accurately. In the process of packaging the optical module, it is more efficient to align the light source in the VCSEL array, and the difficulty of packaging the optical module can be reduced, and package efficiency of the optical module can be improved.

In detail, FIG. 2 shows a working schematic diagram of the package module provided by an embodiment of the present application. FIG. 2 includes a VCSEL array 1, a collimating metalens array 2, a first structural element 3, and a detector 64. It should be noted that the shape of the whole first structural element 3 includes but is not limited to: circular, square, hexagonal ring; and the shape of the hole region in the center of the first structural element 3 includes but is not limited to circular, rectangular, rectangular, and hexagonal.

FIG. 3 shows a schematic diagram of the first structural element 3 in the package module provided by one embodiment of the present application. As shown in FIG. 2 and FIG. 3, in the package module, the first structural element 3 includes a substrate 31 and a vertical eave 32. In the embodiment, the shape of the first structural element and the second structural element is a ring. The shape of the substrate 31 and the vertical eave 32 is a ring. It should be noted that the shape of the whole first structural element 3 and the whole second structural element 4 includes and is not limited to the circle ring, the square ring and the hexagonal ring. And the shape of the hole at the center of the first structural element 3 and the shape of the hole at the center of the vertical eave 32 includes and is not limited to circle, square and hexagon.

The vertical eave 32 is set on the first surface 310 of the substrate 31, and the first surface 310 is a plane. The vertical eave 32 surrounds a hole region of the center of the first surface 310. And an inner wall of the vertical eave 32 and the first surface 310 form a first step structure 33, and the collimating metalens array 2 is fixed to the first step structure 33. The size of the first structure 3 is larger than the size of the collimating metalens array 2, so it is less difficult to adjust the position of the first structural element 3 directly than to adjust the position of the collimating metalens array 2 directly. The first step structure of the first structural element can ensure the processing accuracy, so the collimating metalens array 2 fixed by the first step structure 33 can ensure the position accuracy of the collimating metalens array 2. The position of collimating metalens array 2 can be adjusted indirectly by adjusting the position of the first structural element 3. Therefore, in the optical module provided by the application, it is more efficient to align the centers of the VCSELs in the VCSEL array 1 with the centers of the collimating metalenses in the collimating metalens array 2, which reduces the package difficulty of the optical module and improves the package efficiency of the optical module.

Moreover, it should be noted that although the first structural member 3 is described as two sub-structures (substrate 31 and vertical eave 32), and it does not mean that the first structural element 3 is two separate parts in the physical structure. It is understandable that the first structural element 3 may be an integrated physical structure.

In one embodiment, the projection of the effective region of the collimating metalens array 2 on the first surface is inside the hole region of the first surface 310. In this way, the parallel lights obtained by the collimating metalens array 2 will not be blocked after being emitted vertically from the effective region.

In one embodiment, the first surface 310 of the substrate 31 faces toward the VCSEL array 1. In this situation, if a direction of the light propagation is recorded as from the bottom to the top, the vertical eave 32 is set below the substrate 31. Compared with the substrate 313, the vertical eave 32 fixed to the first step structure 33 is closer to the VCSEL array 1. Since the required working distance between the collimating metalens array 2 and the VCSEL array 1 is usually very short, the lowest distance between the collimating metalens array 2 and the VCSEL array 1 can be reduced by setting the first surface 310 of the substrate 31 facing toward the VCSEL array 1, so as to adjust the distance between the collimating metalens array 2 and the VCSEL array 1 to the required working distance. It is beneficial to adjust the distance between the collimating metalens array 2 and VCSEL array 1 to a required working distance.

In one embodiment, the height of the first step structure 33 is less than the height of the collimating metalens array 2.

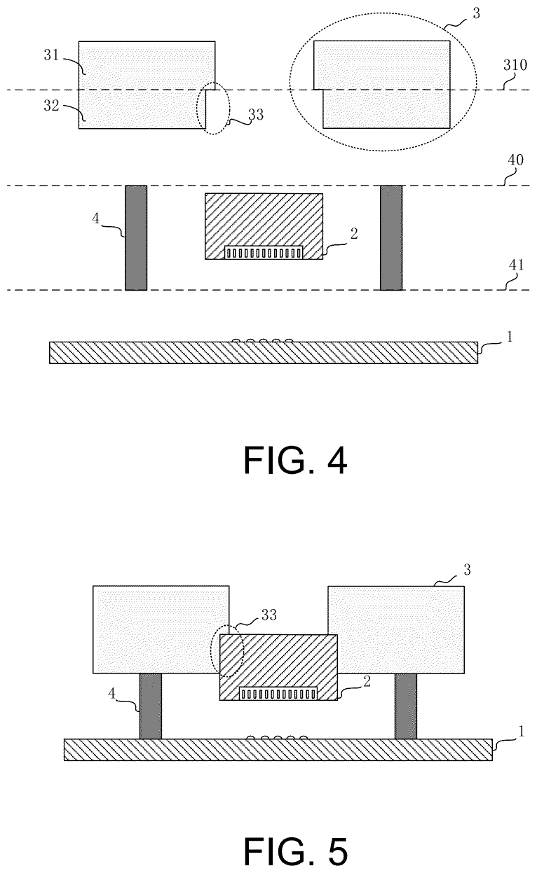

FIG. 4 shows a section view of the package module provided by the embodiment. As shown in FIG. 4 and FIG. 5, the package module provided by the present application includes a VCSEL array 1, a collimating metalens array 2, a first structural element 3 and a second structural element 4. The package module includes a second structural element 4. In the present application, a third surface 40 of the second structural element 4 and the first structural element 3 are fixed together, and a fourth surface 141 of the second structural 4 element and an outgoing surface of the VCSEL array are fixed together. The third surface 40 and the fourth surface 41 are planes; and the third surface 40 and the fourth surface 41 are parallel. Therefore, the centers of the VCSELs are aligned with the centers of the metalenses.

As shown in FIG. 4 and FIG. 5, in one embodiment, the first surface 310 of the substrate 31 of the first structural element 3 faces toward the VCSEL array 1, and the outer wall of the vertical eave 32 is aligned with the outer wall of the substrate 31. In this situation, the third surface 40 of the second structural element and a surface facing toward the VCSEL array 1 of the vertical eave 32 are fixed together.

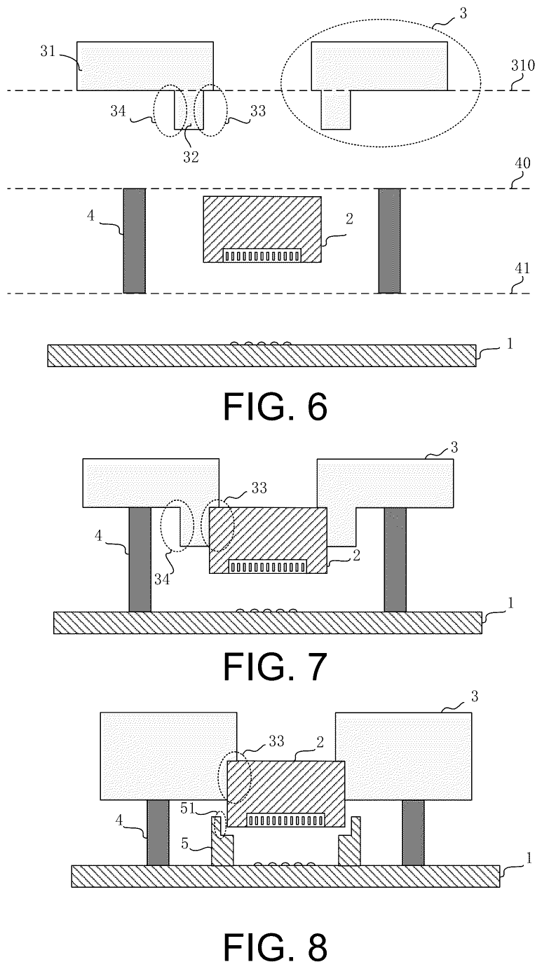

FIG. 6 shows a sectional diagram of the second structural element of the package module and the optical module provided in one embodiment of the present application when working with the optical module. FIG. 7 shows a sectional view of the second structural element 4 of the package module and the optical module provided in one embodiment of the present application. As shown in FIG. 6 and FIG. 7, in one embodiment, the first surface 310 of substrate 31 of the first structural element 310 faces toward the VCSEL array 1. The outer wall of the vertical eave 32 and the first surface 310 are combined to be a second step structure 34, that is, the outer wall of the vertical eave 32 is within the range of the first surface 310, and doesn't touch the edge of the first surface 310 (namely, the outer wall of the vertical eave 32 doesn't touch the outer wall of the substrate 31).

In this situation, the third surface 40 of the second structural element 4 may be fixed to the surface of the VCSEL array 1, or may be fixed to the platform of the second step structure 34. And the platform of the second structure 34 refers to the portion of the second step structure 34 belonging to the first surface 310.

When the distance between the collimating metalens array 2 and the VCSEL array 1 is smaller, the distance between the surface toward the VCSEL array 1 of the vertical eave 32 and the VCSEL array 1 may be too small. It is different to set the second structural element 4 between the two elements. The distance between the platform of the second step structure 34 and the VCSEL array 1 is greater than the distance between the surface toward the VCSEL array 1 of the vertical eave 32 and the VCSEL array 1, so it is more beneficial to set the second structural element 4 by fixing the third surface 40 to the platform of the second step structure 34.

In one embodiment, the second structural element 4 and the third surface 40 are fixed by dispensing.

In one embodiment, the fourth surface 41 of the second structural element 4 and the outgoing surface of the VCSEL array 1 are fixed by dispensing.

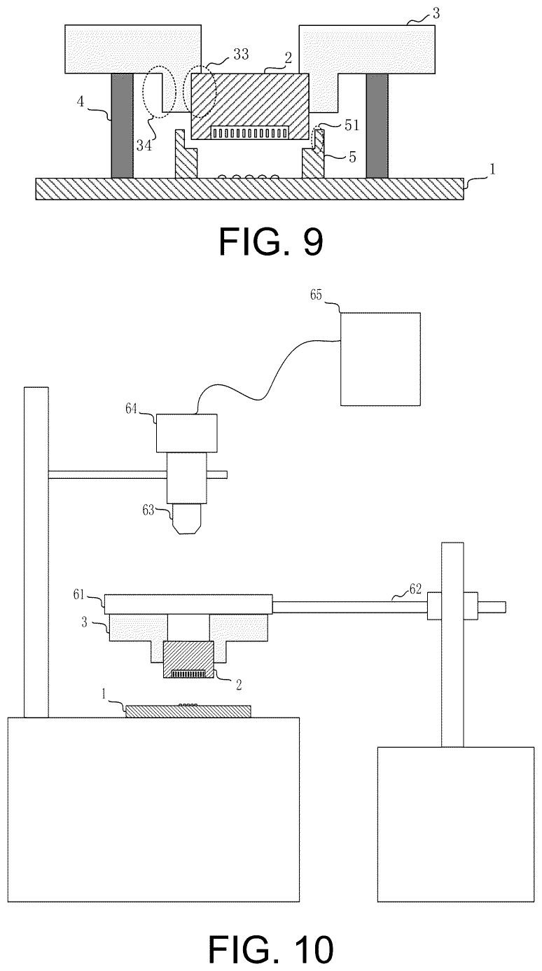

FIG. 8 shows a sectional view of the second structural element and the optical module provided by one embodiment of the present application. FIG. 9 shows a sectional view of the optical module provided by one embodiment of the present application. As shown in FIG. 8 and FIG. 9, in one embodiment, a protective element 5 is provided on the outgoing surface of the VCSEL array 1. In this embodiment, the VCSEL of the VCSEL array 1 is located in the central area of the VCSEL array 1 to protect the structural safety of the VCSELs, the protective element 5 surrounds the center of the VCSEL array 1.

Further, when adjusting the distance between the collimating metalens array 2 and the VCSEL array 1, in order to avoid causing damage to the collimating metalens array 2 by connecting the VCSEL array 1, a third step structure 51 is set on an inner wall of one end of the protective element 5 that is closed to the first structural element 3; a projection of an outer wall of the metalens array on the VCSEL array 1 is located at a platform of the third step structure 51. In this way, the collimating metalens array 2 can only recently reach the platform of the third step structure 51, thus ensuring the structural safety of the VCSELs. And the platform of the third step structure 51 refers to a planar portion of the VCSEL array 1 parallel to the third step structure 51.

The collimating metalens array 2 is fixed to the first step structure 33, and the collimating metalens array 2 is able to mount on the third step structure 51. So if ignoring the height of the collimating metalens array 2, as the collimating metalens array 2 gradually approaches to the VCSEL array 1, the vertical eave 32 will eventually make contact with the third stepped structure 51. Obviously, once the vertical eave 32 contacts the third stepped structure 51, the collimating metalens array 2 cannot continue to be close to the VCSEL array 1. In order to avoid the vertical eave 32 and the third step structure 51 causing an uncertain limitation for the distance between the collimating metalens array 2 and the VCSEL 1, in one embodiment, the sum of the height of the third step structure 51 and the first step structure 33 is configured to be less than the height of the collimating metalens array 2. Thus, the collimating metalens array 2 is able to reach the platform of the third step structure 51.

In summary, in the present application, the size of the first structure 3 is larger than the size of the collimating metalens array 2, so it is less difficult to adjust the position of the first structural element 3 than to adjust the position of the collimating metalens array 2 directly. The first step structure of the first structural element can ensure the processing accuracy, so the collimating metalens array 2 is fixed by the first step structure 33 to ensure the position accuracy of the collimating metalens array 2. The position of collimating metalens array 2 can be adjusted indirectly by adjusting the position of the first structural element 3 directly. Therefore, in the package optical module provided by the application, it is more efficient to align the center of the VCSELs in the VCSEL array 1 with the center of metalenses of the collimating metalens array 2, thus reducing the package difficulty of the optical module and improves the package efficiency of the optical module.

A detection system also is provided to test the optical module as mentioned above. And the detection system includes: a detector 64; the lights emitted by the VCSEL array 1 pass through the effective region and then the lights pass through the hole region of the substrate of the collimating metalens array 2 by the fixation of the first structural element 3, then the lights are incident to the detector 64. The detector 64 is used to detect the optical performance of the received lights and obtain the results of the optical performance.

In one embodiment, the detector 64 further includes at least one assembly of a near-infrared camera, a laser beam analyzer and an optical power meter. Specifically, the near-infrared camera is used to image the invisible lights of a central wavelength of 810 nm. The laser beam is used to detect the degree of collimation of the lights. The optical power is used to detect optical power.

In one embodiment, the detection system further includes a clamp 61 and a movement element. The first structural element 3 is fixed to the clamp 61, and the clamp 61 is fixed to the movement element. Therefore, with the moving of the movement element, the position of the collimating metalens array 2 fixed to the first structural element is adjusted. Thus, the centers of the VCSELs of the VCSEL array 1 are aligned with the centers of the metalenses of the collimating metalens array 2.

In one embodiment, the detection system further includes a display 65; the display 65 is linked to the detector 64. The display is used to visually display the optical information detected by the detector 64, so as to assist the alignment of the centers of the VCSELs with the centers of the metalenses. And The display is used to visually display the test results.

FIG. 10 shows a schematic diagram of the layout of the detection system provided in an embodiment of this application is shown. As shown in FIG. 10, in one embodiment, because the volume of the VCSEL array 1 and the collimating metalens array 2 are small, the detection for a relative distance between the VCSEL array 1 and the collimating metalens array 2 is detected by a microscope. Therefore, the centers of VCSELs of the VCSEL array 1 are aligned with the centers of the metalenses of the metalens array 2.

In detail, the VCSEL array 1 is set on the first carrier. The collimating metalens array 2 is fixed to the first structural element 3 and the first structural element 3 is fixed to the clamp 61 (example for, the first structural element 3 is fixed to the clamp 61 by the screw), and the clamp 61 is fixed to the rod 62. The rod 62 is fixed to the six-axis displacement platform. The rod 62 is able to rotate 360° around the central axis by controlling the six-axis displacement platform. In this way, the rod 62 may change the orientation of the collimating metalens array 2. And the rod 62 is able to move upward vertically and horizontally, and the collimating metalens array 2 moves upward vertically. In this way, the relative position and the vertical distance between the collimating metalens array 2 and the light source 1 can be changed.

The objective 63 of the microscope is set directly above the illumination region of the VCSEL array 1, and the detector 64 is electrically connected to display 65. The detector 64 may be a near-infrared camera. Thus, the display 65 can display in real-time the horizontal relative position of the collimating metalens array 2 and the VCSEL array 1, so the centers of the VCSELs are aligned with the centers of the metalenses.

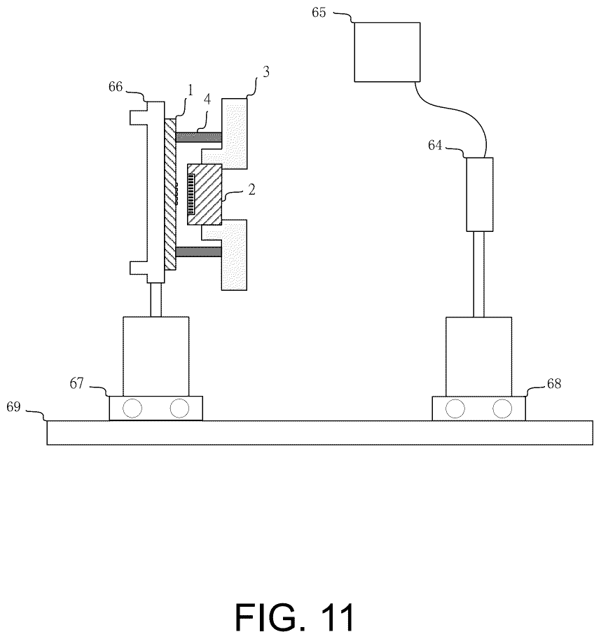

FIG. 10 shows a schematic layout of the detection system provided in one embodiment of the present application. As shown in FIG. 10 and FIG. 11, after aligning the centers of VCSELs with the centers of the metalenses with the aid of the microscope, the second structure element 4 is set between the VCSEL array 1 and the first structural element 3. Then the second structural element 4 is fixed to the VCSEL array 1 and the first structural element 3 respectively, then the first structure element 3 is removed from the clamp 61, so as to obtain an independent integrated module for collimation consisting of the VCSEL array 1, the collimating metalens array 2, the first structural element 3, and the second structural element 4.

After obtaining the optical module, the optical module is fixed to the adjusted support 21. Due to the mechanical error, when the optical module is fixed to the adjusted support 21, the VCSEL array 1 and the collimating metalens array 2 are usually not perpendicular to the horizontal plane, so the adjusted support 21 is arranged as a pitch motion relative to the horizontal plane, that the pitch angle of the VCSEL array 1 and the collimating metalens array 2 are adjusted to pose perpendicular to the horizontal plane. Correspondingly, the detector 64 is also set in a posture perpendicular to the horizontal plane.

In one embodiment, the detection system further includes a first carrier, a first sliding rail 67, a guide rail 69; the adjustable support 21 is fixed to the first carrier; the first carrier is set on the first sliding rail 67; the first sliding rail 67 is set on the guide rail 69.

In one embodiment, the detection system further includes a second carrier, a second sliding rail 68, and a guide rail 69; the detector is fixed to the second carrier; the second carrier is set on the second sliding rail 68; the second sliding rail 68 is set on the guide rail 69.

The relative distance between the optical module and the detector 64 is adjustable freely to fit different detection requirements of different relative distances.

The detector 64 transports the optical information to the display 65, and the display 65 will show the results of the detection directly.

The above is only a specific embodiment of the embodiments of this disclosure, but the scope of protection of the embodiment of this disclosure is not limited to this. And those skilled in the field can easily think of any change or substitution for this disclosure, which should be covered within the protection scope of this disclosure. Therefore, the scope of the protection of the present disclosure shall be the scope of the claims.

What is claimed is:

1. An optical module, wherein the optical module comprises a VCSEL array, a collimating metalens array;
the collimating metalens array is set on an outgoing side of the VCSEL array and are parallel to the VCSEL array;
the VCSEL array comprises a plurality of VCSELs, and the collimating metalens array comprises a plurality of collimating metalenses; the collimating metalens array comprises an effective region for light modulation; a projection of an illumination region of the VCSEL array on the collimating metalens array is inside the effective region of the collimating metalens array;
a plurality of projections of centers of the VCSELs of the VCSEL array on the effective region overlaps centers of the collimating metalenses of the collimating metalens array.

2. The optical module according to claim 1, wherein each VCSEL in the VCSEL array emits light has a central wavelength of 810 nm.

3. The optical module according to claim 1, wherein each VCSEL in the VCSEL array emits light has a full angle of divergence of 25°.

4. The optical module according to claim 1, wherein a distance between the VCSEL array and the collimating metalens array is greater than or equal to 250 μm, and is less than or equal to 350 μm.

5. The optical module according to claim 4, wherein a distance between the VCSEL array and the collimating metalens array is greater than or equal to 280 μm, and is less than or equal to 320 μm.

6. The optical module according to claim 1, wherein a number of the collimating metalenses of the collimating metalens array is greater than or equal to a number of the VCSELs of the VCSEL array.

7. The optical module according to claim 1, wherein the effective region of the collimating metalens array faces toward the VCSEL array.

8. A package module, wherein the package module is applied to the package of the optical module claimed as claim 1, and the package module comprises a first structural element;
a shape of the first structural element is a ring; the first structural element comprises a substrate and a vertical eave, and a shape of the substrate is a ring and a shape of the vertical eave is a ring; the vertical eave is set on a first surface of the substrate, and the vertical eave surrounds a hole region of a center of the first surface; an inner wall of the vertical eave and the first surface form a first step structure, and the collimating metalens array is fixed to the first step structure.

9. The package module according to claim 8, wherein the projection of the effective region of the collimating metalens array on the first surface is inside the hole region of the first surface.

10. The package module according to claim 8, wherein the first surface faces toward the VCSEL array.

11. The package module according to claim 8, wherein a height of the first step structure is less than a height of the collimating metalens array.

12. The package module according to claim 8, wherein the package module comprises a second structural element,
wherein a third surface of the second structural element and the first structural element are fixed together, and a fourth surface of the second structural element and an outgoing surface of the VCSEL array are fixed together; the third surface and the fourth surface are planes.

13. The package module according to claim 12, wherein an outer wall of the vertical eave is aligned with an outer wall of the substrate; and the third surface is fixed to a surface facing toward the VCSEL array of the vertical eave.

14. The package module according to claim 12, an outer wall of the vertical eave and the first surface form a second step structure.

15. The package module according to claim 14, wherein the third surface is fixed to a platform of the second step structure.

16. The package module according to claim 12, wherein the third surface and the first structural element are fixed together by dispensing.

17. The package module according to claim 12, wherein the fourth surface and an outgoing surface of the VCSEL array are fixed together by dispensing.

18. The package module according to claim 8, wherein a protective element is set on an outgoing surface of the VCSEL array, and the protective element surrounds the center of the VCSEL array.

19. The package module according to claim 18, wherein a third step structure is set on an inner wall of one end of the protective element that is close to the first structural element; a projection of the protective element of an outer wall of the collimating metalens array on the VCSEL array is located at a platform of the third step structure.

20. The package module according to claim 18, wherein a sum of a height of the third step structure and the height of the first step structure is less than the height of the collimating metalens array.
